(19) United States
(12) Patent Application Publication
(10) Pub. No.: US 2008/0121372 A1
(43) Pub. Date: May 29, 2008

(54) HEAT DISSIPATION DEVICE

(75) Inventors: SHI-WEN ZHOU, Shenzhen (CN); CHUN-CHI CHEN, Taipei Hsien (TW); BAO-CHUN CHEN, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Taipei Hsien (TW)

(21) Appl. No.: 11/626,720

(22) Filed: Jan. 24, 2007

(30) Foreign Application Priority Data
Nov. 24, 2006 (CN) 200610157059.7

(51) Int. Cl. H05K 7/20

(52) U.S. Cl. 165/80.3; 165/104.33; 361/700

(57) ABSTRACT

A heat dissipation device includes a heat sink including a base for contacting with an electronic device, a fin set having a plurality of fins, and a heat pipe having a first section thermally attached to the base and a second section extending through the fin set. Each of the fins has an airflow guiding structure in a passage formed between two neighboring fins. A fan is attached to a front of the heat sink. An airflow provided by the fan flows into the passage and is then directed by the airflow guiding structure to joints of the second section of the heat pipe with the fins where more heat from the electronic device is accumulated. The guiding structure includes two guiding sidewalls extending in a diverging manner from the fan toward a rear of the heat sink.

### BACKGROUND OF THE INVENTION

1. Field of the Invention

The present invention relates generally to a heat dissipation device, and more particularly to a heat dissipation device used for dissipating heat generated by an electronic device.

2. Description of Related Art

With advancement of computer technology, electronic devices operate rapidly. It is well known that the more rapidly the electronic devices operate, the more heat they generate. If the heat is not dissipated duly, the stability of the operation of the electronic devices will be impacted severely. Generally, in order to ensure the electronic device to run normally, a heat dissipation device is used to dissipate the heat generated by the electronic device.

Conventionally, a heat dissipation device comprises a heat sink which has a base and a plurality of fins on the base. The fins each of which is flat sheet are parallel to and spaced from each other. Therefore, pluralities of passages are defined between the fins for airflow passing therethrough. Usually, the heat dissipation device further comprises a fan located aside the heat sink for providing forced airflow to the heat sink. Generally, the heat generated by the electronic device accumulates at the base, which is transferred from the base to the fins by at least a heat pipe. However, there is no sufficient airflow from the fan distributed to joints of the heat pipe and the fins to duly remove the heat accumulated therein. Heat dissipation capability of the heat dissipation device cannot meet heat dissipation demand of the electronic device. Consequently, in order to improve the heat dissipation capability, the heat dissipation device needs to be improved.

What is needed, therefore, is a heat dissipation device having an improved heat dissipation capability, wherein airflow generated by a fan of the heat dissipation device can be more effectively guided to heat accumulating areas of the heat dissipation device to take heat away therefrom.

### SUMMARY OF THE INVENTION

A heat dissipation device includes a heat sink including a base for contacting with an electronic device, a fin set having a plurality of fins and located on the base, and a heat pipe having a first section thermally attached to the base and a second section extending through the fin set. Each of the fins has an airflow guiding structure extending into a passage formed between two corresponding neighboring fins. A fan is attached to the heat sink for providing forced airflow to the heat sink. The airflow provided by the fan flows into the passage and is then directed to joints of the second section of the heat pipe and the fins where more heat from the electronic device is accumulated than any other place of the fins.

Other advantages and novel features of the present invention will become more apparent from the following detailed description when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an assembled view of a heat dissipation device in accordance with a preferred embodiment of the present invention;

FIG. 2 shows an exploded, isometric view of the heat dissipation device of FIG. 1;

FIG. 3 is an enlarged view of a fin of the heat dissipation device of FIG. 2; and

FIG. 4 is an enlarged view of a fin of a heat dissipation device in accordance with an alternative embodiment of the present invention.

### DETAILED DESCRIPTION OF THE INVENTION

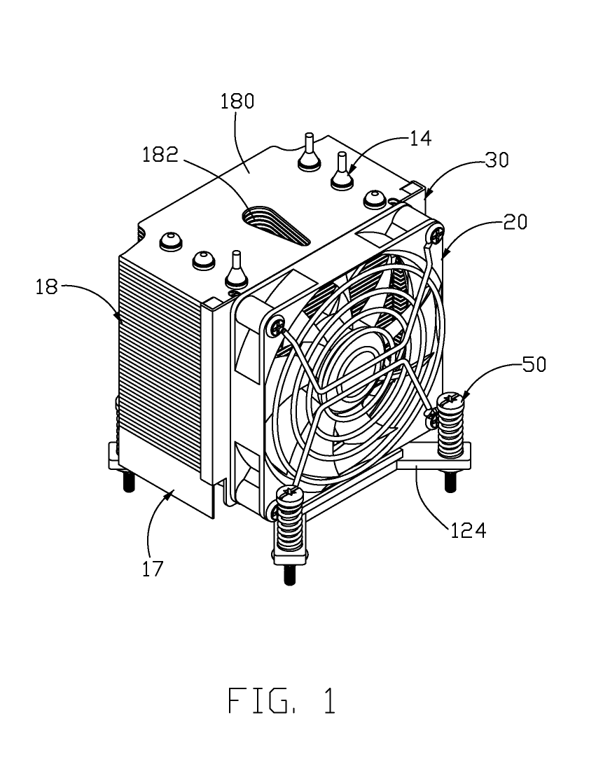

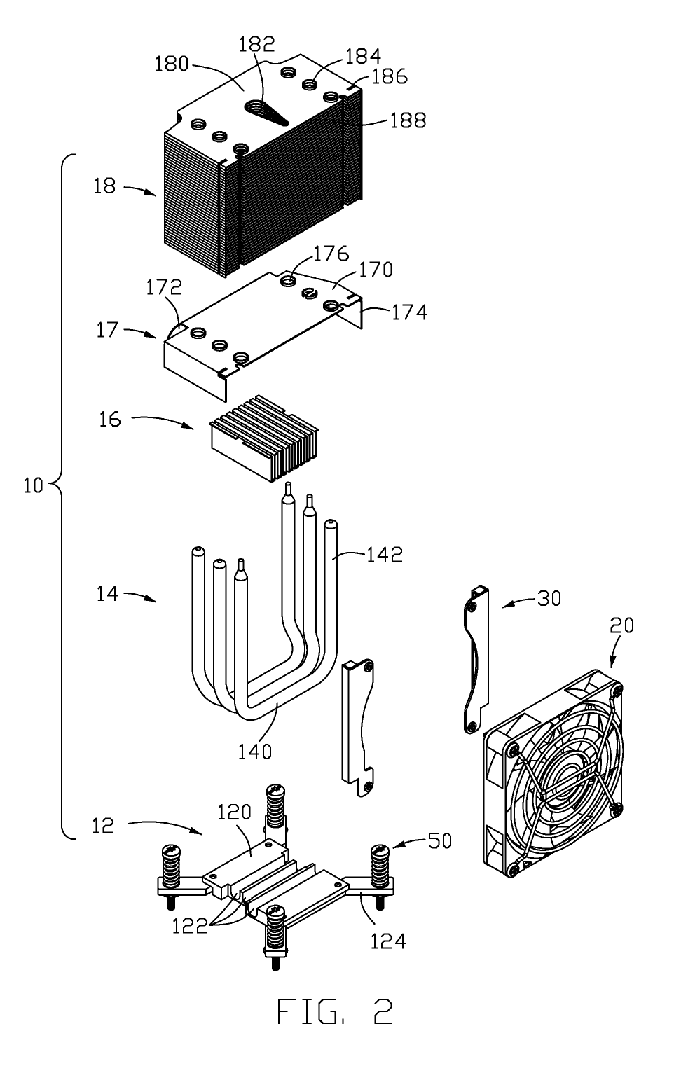

Referring to FIGS. 1 and 2, a heat dissipation device in accordance with a preferred embodiment of the present invention is illustrated. The heat dissipation device generally comprises a heat sink 10 and a fan 20 attached to a front of the heat sink 10 by a pair of fan holders 30. The heat sink 10 comprises a base 12, a fin set 18 located above the base 12, three heat pipes 14 connecting the base 12 and the fin set 18 for transferring heat from the base 12 to the fin set 18.

The base 12 comprises a substantially rectangular heat receiver 120, and four fixing legs 124 extending outwardly from four corners of the heat receiver 120. The heat receiver 120 is made of a material with good heat conductivity, such as copper, aluminum or the like. A top face of the heat receiver 120 defines three parallel grooves 122 therein. A bottom surface of the heat receiver 120 is flat for thermally contacting with a heat generating electronic device (not shown), such as a CPU, mounted on a printed circuit board (not shown). Each of the fixing legs 124 defines a fixing hole (not labeled) adjacent to a distal end thereof for extension of a fastener 50 therethrough. The fasteners 50 are used for fixing the heat dissipation device to the printed circuit board.

The three heat pipes 14 transfer heat from the base 12 to the fin set 18. Each heat pipe 14 comprises a first section 140 and two parallel second sections 142 perpendicularly and upwardly extending from two ends of the first section 140. An arc transitional corner (not labeled) is formed at each joint of the first section 140 and the second section 142. The first sections 140 of the heat pipes 14 are received in the corresponding grooves 122 of the base 12. The second sections 142 of the heat pipes 14 extend upwardly beyond the base 12 and through the fin set 18.

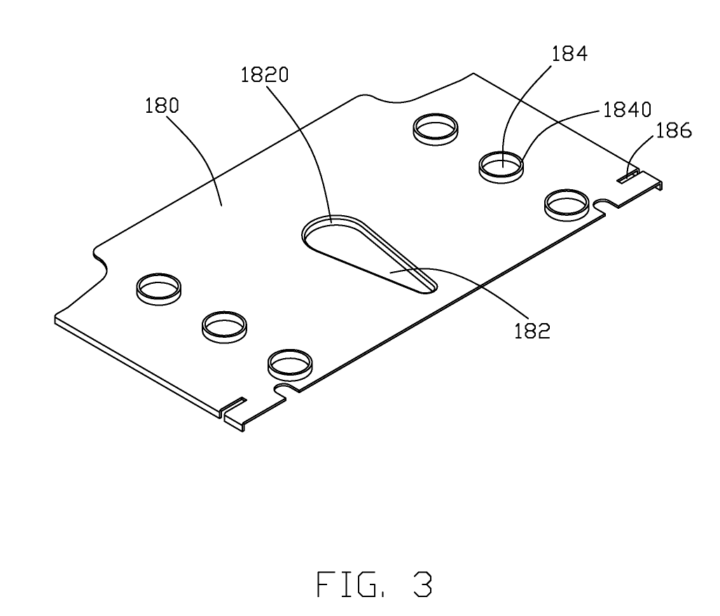

Referring also to FIG. 3, the fin set 18 comprises a plurality fins 180 stacked together. The fins 180 are spaced from each other and parallel to the base 12. Two rows of through holes 184 are defined respectively adjacent to two opposite sides of the fin 180. Each through hole 184 is circumferentially surrounded by a collar 1840 extending upwards from the fin 180. The through holes 184 and the collars 1840 of the fins 180 of the fin set 18 cooperatively form a plurality of channels in the fin set 18, for thermally received the second sections 142 of the heat pipes 14, respectively. The fin 180 defines two short slots 186 in two opposite lateral edges of the fin 180 and adjacent to the front of the fin set 18. These slots 186 of the fins 180 of the fin set 18 cooperatively define two grooves (not labeled) for fixing the fan holders 30 on the front of the fin set 18. The fan 20 is secured on the fan holders 30 by four screws (not labeled).

Every two neighboring fins 180 define an airflow passage 188 therebetween for allowing airflow generated by the fan 20 to flow therethrough. Each fin 180 defines an airflow guiding structure (not labeled) located at a centre of an air passage 188 formed between the two corresponding fins 180. In this embodiment of the present invention, the airflow guiding structure comprises a hole 182 with a shape like a teardrop, having an airflow guiding sidewall 1820 extending downwards and perpendicularly from an edge of the teardrop-like hole 182. The teardrop-like hole 182 has a cusp (not labeled) facing toward and located adjacent to the front of the fin set 18 where the fan 20 is mounted. Two lateral guiding sidewalls 1820 separated by the cusp extend in a direction along which the airflow generated by the fan 20 flows, while a distance between two ends of the two lateral guiding sidewalls 1820 proximal to the fan 20 is smaller than that between two ends of the lateral guiding sidewalls 1820 distant from the fan 20. In other words, the lateral guiding sidewalls 1820 extend in a diverging manner from the cusp of the teardrop-like hole 182 toward a rear of the fin set 18. A height of the guiding sidewalls 1820 is equal to a distance between the two neighboring fins 180. The airflow from the fan 20 entering the passage 188 is partly reflected and guided by the two lateral guiding sidewalls 1820 to flow past joints of the heat pipes 14 and the fin set 18 at two sides of the fin set 18, when the airflow impinges upon the two lateral guiding sidewalls 1820. In this embodiment, the joints of the heat pipes 14 and the fin set 18 are located at places where the channels of the fin set 18 receives the second sections 142 of the heat pipes 14. The heat accumulated in these areas is thus brought into surrounding environment more quickly due to more airflow flowing therethrough.

The heat sink 10 further comprises a fin unit 16 located between the base 12 and the fin set 18, and a guiding fin 17 sandwiched between the fin unit 16 and the fin set 18. The fin unit 16 is folded from a piece of metal sheet, and has a bottom face thermally contacting the top face of the heat receiver 120 of the base 12 and a top face contacting a bottom face of the guiding fin 17. The fin set 18 is stacked on the guiding fin 17.

The guiding fin 17 functions as a fan duct to guide a part of the airflow generated by the fan 20 to flow toward the printed circuit board (not shown) on which the heat dissipating device is mounted, whereby the part of the airflow can be used to dissipate heat generated by other electronic component(s) near the CPU. The guiding fin 17 comprises a body 170 parallel to the fins 180 of the fin set 18. The body 170 is spaced from the heat receiver 120. An inclined sidewall 172 is bent downwardly from a rear end of the body 170. A portion of the airflow generated by the fan 20 is first guided to flow through the fin unit 16, and then is guided to flow downwards towards the printed circuit board by the inclined sidewall 172 of the guiding fin 17. Two opposite baffle walls 174 extend perpendicularly downwardly from two lateral sides of the body 170 respectively. The body 170 has two rows of through holes 176 communicating with the channels of the fin set 18, respectively, for the second sections 142 of the heat pipes 14 extending therethrough.

In use, the heat receiver 120 of the base 12 has the bottom surface contacting with the electronic device (i.e., the CPU) and absorbs heat from the electronic device. Part of the heat in the heat receiver 120 of the base 12 is directly transferred to the fin unit 16, and part of the heat is absorbed by the first sections 140 of the heat pipes 14. Subsequently, the heat in heat pipes 14 is transferred to the fins 180 of the fin set 18 by the second sections 142 of the heat pipes 14. The heat in the fin set 18, the fin unit 16 and the heat pipes 14 is duly dissipated to the surrounding environment under work of the fan 20.

As described above, each fin 180 of the fin set 18 of the heat dissipation device forms two guiding sidewalls 1820 leaning towards the second sections 142 of the heat pipes 184; therefore, the airflow from the fan 20 is reflected to the joints of the second sections 142 of the heat pipes 14 and the fin set 18 by the guiding sidewalls 1820. As a result, the heat either in the second sections 142 of the heat pipes 14 or the joints around the second sections 142 is duly dissipated to ambient air by the airflow since more air can flow therethrough. Thus, partially overheating of heat dissipation device is avoided. So, heat dissipation capability of the heat dissipation device of the present invention is improved in comparison with the heat dissipation devices in accordance with the related art.

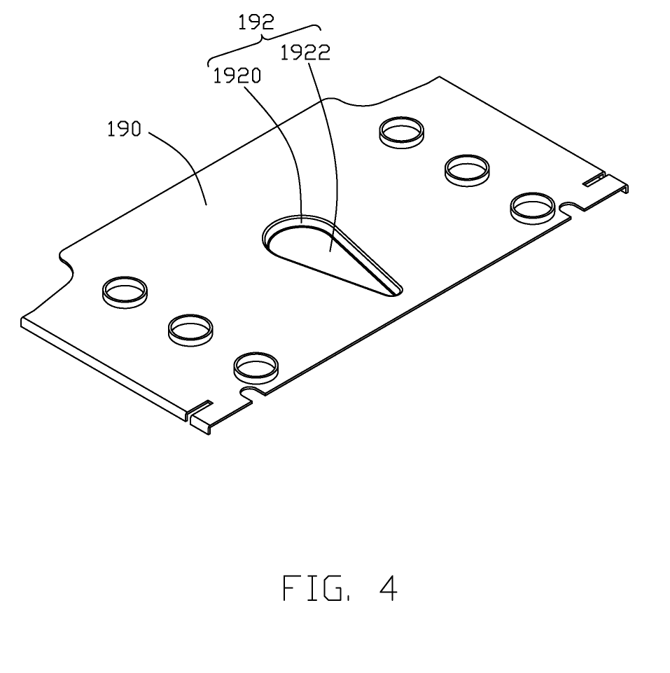

Referring to FIG. 4, a heat dissipation device in accordance with an alternative embodiment of the present invention is shown. All components of the heat dissipation device are identical with those of the aforementioned heat dissipation device according to the first preferred embodiment, except fins 190 of the fin set.

The fins 190 in the alternative embodiment each have an airflow guiding structure different from that of the fins 180 in the first preferred embodiment. The guiding structure of the fins 190 is a concaved protrusion 192 having a sidewall 1920 perpendicular to the fins 190 and a bottom wall 1922 inside and connecting a bottom edge of the sidewall 1920. The sidewall 1920 also has a cusp that separates the sidewalls 1920 into two lateral guiding sidewalls 1920. The two lateral guiding sidewalls 1920 work in a principle identical to that of the two lateral guiding sidewalls 1820 of the fins 180.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device for dissipating heat generated by an electronic device, the heat dissipation device comprising:
a heat sink comprising:
a base for contacting with the electronic device;
a fin set having a plurality of fins;
a heat pipe having a first section thermally attached to the base and a second section extending through the fin set, each of the fins having an airflow guiding structure in a passage formed between two neighboring fins; and
a fan attached to the heat sink for providing airflow to the heat sink;
wherein the airflow provided by the fan flows into the passage and is then reflected and guided by the airflow guiding structure to joints of the second section of the heat pipe and the fins where more heat from the electronic device is accumulated than any other place of the fins.

2. The heat dissipation device of claim 1, wherein the airflow guiding structure comprises two lateral guiding sidewalls extending in a direction along which the airflow provided by the fan flows through the heat sink, while a distance between two ends of the two lateral guiding sidewalls proximal to the fan is smaller than that between other two ends of the lateral guiding sidewalls distant from the fan.

3. The heat dissipation device of claim 2, wherein a height of the two lateral guiding sidewalls is equal to a distance between the two neighboring fins of the fin set.

4. The heat dissipation device of claim 3, wherein the fins each define a hole, and the two lateral guiding sidewalls are formed at an edge of the hole.

5. The heat dissipation device of claim 3, wherein the fins each define a concaved protrusion having a sidewall defining the airflow guiding sidewalls.

6. The heat dissipation device of claim 1, wherein the heat pipe is substantially U-shaped having two second sections extending through the fins of the fin set and located at two sides of the airflow guiding structure of the fins.

7. The heat dissipation device of claim 6 further comprising a guiding fin, wherein the fan is attached to a front the heat sink and the guiding fin is for guiding a part of the airflow generated by the fan to a lower, rear part of the heat sink.

8. A heat dissipation device used for dissipating heat generated by an electronic device, the heat dissipation device comprising:
a heat sink comprising a base and a plurality of fins on the base, a plurality of passages being defined between adjacent fins, each of the fins having an airflow guiding structure in a corresponding passage;
a fan attached to the heat sink for providing forced airflow to the heat sink;
wherein the airflow guiding structure guides a stream of the airflow provided by the fan to heat-accumulating portions of the fins.

9. The heat dissipation device of claim 8, wherein the airflow guiding structure comprises two lateral guiding sidewalls extending in a direction along which the airflow provided by the fan flows through the heat sink, while a distance between two ends of the two lateral guiding sidewalls proximal to the fan is smaller than that between other two ends of the lateral guiding sidewalls distant from the fan.

10. The heat dissipation device of claim 9, wherein a height of the two lateral guiding sidewalls is equal to a distance between the adjacent fins.

11. The heat dissipation device of claim 1 O, wherein the fins each define a teardrop-like hole and the lateral guiding sidewalls of each of the fins is formed at an edge of the hole..

12. The heat dissipation device of claim 10, wherein the fins each define a teardrop-shaped concaved protrusion having a sidewall defining the two lateral guiding sidewalls.

13. The heat dissipation device of claim 8, wherein the heat sink further comprises a heat pipe thermally connecting the base and the fins together.

14. The heat dissipation device of claim 1 3, wherein the heat-accumulating portions of the fins comprise places where the heat pipe and the fins joint together.

15. The heat dissipation device of claim 14, wherein the heat pipe is substantially U-shaped having a first section in thermally connection with the base of the heat sink and two second sections extending through the fins and located at two sides of the airflow guiding structures of the fins.

16. The heat dissipation device of claim 8, wherein the heat sink further comprises a plurality of heat pipes spaced from each other along a direction the airflow provided by the fan flowing through the heat sink, each heat pipe having a first section thermally connecting with the base of the heat sink and at least a second section extending through the plurality of fins, the airflow guiding structure guiding the stream of the airflow provided by the fan to heat-accumulating portions of the fins which are located at joints between the fins and the at least a second section of the each heat pipe.

17. The heat dissipation device of claim 8, wherein the heat sink further comprises a guiding fin between the base and the plurality of fins, and wherein the fan is attached to a front of the heat sink and the guiding fin guides a part of the airflow generated by the fan to a lower, rear part of the heat sink.

18. The heat dissipation device of claim 16, wherein the heat sink further comprises a guiding fin between the base and the plurality of fins, and wherein the fan is attached to a front of the heat sink and the guiding fin guides a part of the airflow generated by the fan to a lower, rear part of the heat sink.

19. The heat dissipation device of claim 17, wherein the heat sink further comprises a fin unit located between and thermally connecting with the guiding fin and the base of the heat sink.

20. The heat dissipation device of claim 18, wherein the heat sink further comprises a fin unit located between and thermally connecting with the guiding fin and the base of the heat sink.
